(19) United States
(12) Patent Application Publication
(10) Pub. No.: US 2014/0252379 A1
(43) Pub. Date: Sep. 11, 2014

(54) PHOTOCONDUCTIVE ANTENNAS, METHOD FOR PRODUCING PHOTOCONDUCTIVE ANTENNAS, AND TERAHERTZ TIME DOMAIN SPECTROSCOPY SYSTEM

(71) Applicant: CANON KABUSHIKI KAISHA, Tokyo (JP)

(72) Inventor: Takahiro Sato, Ebina-shi (JP)

(73) Assignee: CANON KABUSHIKI KAISHA, Tokyo (JP)

(21) Appl. No.: 14/199,870

(22) Filed: Mar. 6, 2014

(30) Foreign Application Priority Data
Mar. 8, 2013 (JP) 2013-046576
Jan. 27, 2014 (JP) 2014-012784

(51) Int. Cl. H01L 31/0304; H01L 31/18

(52) U.S. Cl. CPC H01L 31/03046; H01L 31/1844
USPC 257/85; 438/24

(57) ABSTRACT

A photoconductive antenna that generates and detects a terahertz wave has a substrate, a buffer layer, a first semiconductor layer, a second semiconductor layer, and an electrode in this order. The substrate is made of Si, the buffer layer contains Ge, and the first and second semiconductor layers both contain Ga and As. The element ratio Ga/As of the second semiconductor layer is smaller than the element ratio Ga/As of the first semiconductor layer.

### BACKGROUND OF THE INVENTION

1. Field of the Invention

The present invention relates to a photoconductive antenna, a method for producing a photoconductive antenna, and a terahertz time domain spectroscopy system.

2. Description of the Related Art

In recent years, nondestructive sensing technologies that use electromagnetic radiation from millimeter to terahertz (THz) waves (30 GHz to 30 THz, hereinafter also simply referred to as terahertz waves) have been developed. As a field of application of the electromagnetic radiation in this frequency band, an imaging technology as a means for fluoroscopic examinations safer than X-ray is under development. Spectroscopic technologies to characterize a substance, e.g., to identify the molecular bonding state, by determining the absorption spectrum and complex dielectric constant in the substance, measuring technologies to explore the carrier content, mobility, conductivity, and other characteristics, and analytical technologies for biological molecules have also been developed.

A widely used way to generate and detect terahertz waves is to use a photoconductive antenna. A photoconductive antenna has a particular semiconductor that has a relatively large mobility and a sub-picosecond carrier life, with two electrodes on the semiconductor. The mechanism is as follows: Irradiating the gap between the electrodes with ultrashort pulse laser light while applying a voltage across the electrodes causes excited photocarriers to induce an instantaneous current flow between the electrodes, and the photoconductive antenna emits a terahertz wave with a broad frequency spectrum. The aforementioned measuring and imaging technologies have been studied using terahertz time domain spectroscopy (THz-TDS) systems that use another photoconductive antenna as a detector for terahertz waves.

In a typical semiconductor antenna, the particular semiconductor can be selected from compound semiconductors such as GaAs, InGaAs, AlGaAs, GaAsP, and InGaAsP. In particular, low-temperature-grown GaAs (LT-GaAs) films, grown in the crystalline form in the temperature range of 200° C. to 400° C., are very commonly used (IEEE J Quant. Elect. 28 2464 (1992)). LT-GaAs is grown as a crystal on a semi-insulating GaAs (SI—GaAs) substrate in most cases. This causes various problems while THz waves pass through the SI—GaAs substrate, such as reduced efficiency of use of the power of the THz waves and spectral narrowing, because of the absorption of near-8-THz waves by TO phonons.

These problems can be solved by replacing Si—GaAs, which strongly absorbs THz waves, with a substrate that absorbs only a limited amount of THz waves. In particular, semi-insulating Si is a promising material to replace Si—GaAs GaAs for some reasons such as little loss of THz and the utility thereof as a substrate material for heteroepitaxial growth of GaAs.

Heteroepitaxy, i.e., a technique to coat a Si substrate with a crystal of a different material, or more specifically GaAs or other compound semiconductors, has been actively studied through many ages, and there is even a review article on the history thereof (Physics Uspekhi 51 (5) 437 (2008)). The preceding studies, however, focused on reducing the dislocation density and increasing the area of the growth substrate and were not necessarily to find out a crystal growth technique that could be applied to photoconductive antennas suitable for the generation and detection of THz waves. Many of the past studies used LT-GaAs as a buffer layer to reduce dislocations, and few attempted to grow high-quality LT-GaAs on a Si substrate. The above review article describes a technology that uses Ge as a buffer while growing GaAs, and this approach is known to be disadvantageous because of easy diffusion of Ge into Si and GaAs. When a photoconductive antenna is fabricated on Si or GaAs, diffusion of Ge diffusion can cause the problem of out-of-design performance of the antenna.

While crystal growth techniques have advanced, device fabrication processes have also become actively explored. Japanese Patent No. 2564856 discloses a technology that can be employed when GaAs grown on a Si substrate is used as a functional layer of a device, and this technology includes inserting conductive GaAs or a similar material as an insulating layer between the Si substrate and the GaAs functional layer. Devices that perform the functions thereof when a current flows substantially parallel to a substrate, such as Hall elements and transistors, can be improved in performance, e.g., the power consumption can be lowered, by reducing the leakage current to the substrate. For photoconductive antennas that generate and detect THz waves, technologies to reduce the leakage current to a substrate are also important techniques that can provide positive outcomes such as reduced noise.

It is widely known that threading dislocations in a crystal create unintended current paths and thus cause reduced function of an insulating layer or defects to occur in devices in a functional layer. In general, increasing the thickness of a GaAs coating on Si reduces the threading dislocation density by joining several threading dislocations together. The technology disclosed in the above patent publication also requires that the buffer layer and other GaAs layers under the functional GaAs layer be as thick as several micrometers so that threading dislocations can be reduced.

These publications and other previous studies, as mentioned above, mainly focused on reducing threading dislocations rather than discovering a crystal growth technique that allows a photoconductive antenna suitable for generating and detecting THz waves to be fabricated on a Si substrate. The use of a thick GaAs layer causes the THz waves to be strongly absorbed, resulting in an insufficient power being generated or detected. The structures reached in the preceding studies are therefore unsuitable for photoconductive antennas for generating and detecting THz waves.

Threading dislocations can be significantly reduced by using Ge as a buffer layer. However, the use of Ge as a buffer layer for GaAs growth on a Si substrate requires a structure that prevents the effect of diffusing Ge from affecting the performance of the photoconductive antenna. This issue has been disregarded.

The fabrication of a photoconductive antenna that has a Si substrate and LT-GaAs or a similar compound semiconductor has therefore not been optimized so far.

### SUMMARY OF THE INVENTION

A photoconductive antenna according to an aspect of the invention is a photoconductive antenna that generates and detects a terahertz wave. The photoconductive antenna has a substrate, a buffer layer, a first semiconductor layer, a second semiconductor layer, and an electrode in this order. The substrate is made of Si, the buffer layer contains Ge, and the first and second semiconductor layers both contain Ga and As. The element ratio Ga/As of the second semiconductor layer is smaller than the element ratio Ga/As of the first semiconductor layer.

Further features of the present invention will become apparent from the following description of exemplary embodiments with reference to the attached drawings.

### BRIEF DESCRIPTION OF THE DRAWINGS

FIGS. 1A and 1B illustrate an example of the structure of a photoconductive antenna according to Embodiment 1.

FIG. 2 shows the relationship between the thickness of GaAs and the power absorbed.

FIG. 3 illustrates an example of the structure of a photoconductive antenna according to Embodiment 2.

FIG. 4 illustrates an example of the structure of a photoconductive antenna according to Embodiment 3.

FIG. 5 illustrates an example of the structure of a THz-TDS according to Embodiment 4.

FIGS. 6A and 6B illustrate the structure of a photoconductive antenna of the Example.

FIG. 7 is a TEM image of LT-GaAs.

### DESCRIPTION OF THE EMBODIMENTS

A photoconductive antenna according to an aspect of the invention has a Ga- and As-containing semiconductor layer (a second semiconductor layer) on a Si substrate with a buffer layer made of Ge therebetween. A photoconductive antenna according to an aspect of the invention further has a Ga- and As-containing semiconductor layer (a first semiconductor layer) between the second semiconductor layer and the buffer layer, and the element ratio Ga/As of the second semiconductor layer is smaller than the element ratio Ga/As of the first semiconductor layer. Preferably, the thickness of the first semiconductor layer is in the range of 100 nm to 1 μm, both inclusive. (More preferably, the thickness of the first semiconductor layer is in the range of 100 nm to 250 nm, both inclusive). Such a structure ensures, for example, that while the THz wave generated and to be detected passes through the substrate, the loss of power due to absorption by phonons (near 8- to 10-THz in GaAs) is acceptable, while preventing diffusing Ge and strains in the crystal from reaching the compound semiconductor layers. Because of these advantages, a photoconductive antenna is provided that has a broad and complete frequency spectrum with little loss of performance, with the data complete even near 8 THz.

The following describes preferred embodiments of the invention with reference to the accompanying drawings.

### Embodiment 1

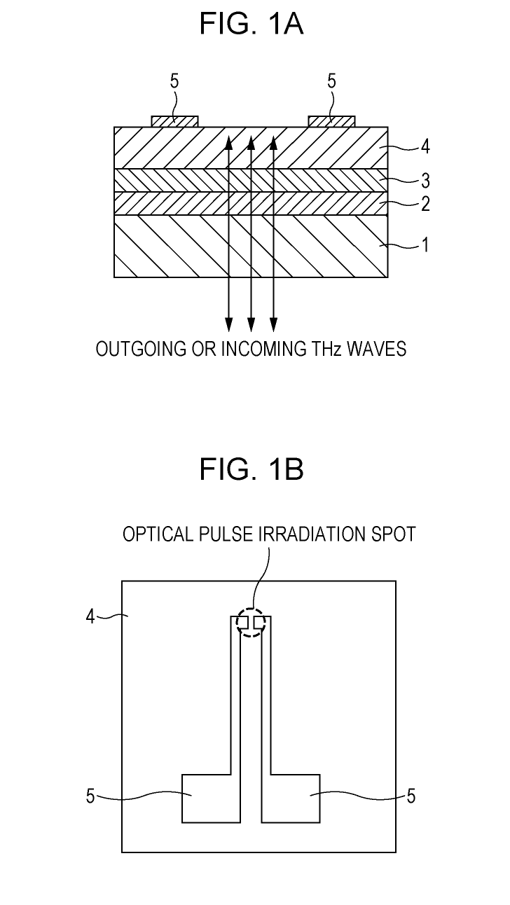

A first embodiment of the invention is described with reference to FIGS. 1A and 1B. FIGS. 1A and 1B are a cross-sectional view and a top view, respectively, of a photoconductive antenna according to this embodiment. FIGS. 1A and 1B illustrate a photoconductive antenna produced by growing crystals of Ge (a Ge layer) 2, GaAs (a first semiconductor layer that contains Ga and As) 3, and LT-GaAs (a second semiconductor layer that contains Ga and As) 4 on a Si substrate 1 in this order and then placing more than one electrode 5.

Low-resistivity silicon would lead to a great loss of THz waves due to absorption by free carriers. Thus the Si substrate 1 is made of semi-insulating Si, preferably having a resistivity of 10 Ω·cm or more. In this embodiment, silicon grown as a crystal with a resistivity of 3 kΩ·cm by the FZ process, which generally provides high-resistivity Si, is used as the Si substrate 1. The orientation of the substrate is (100), and substrates that have an off-angle, i.e., an angle tilted with respect to the orientation, can also be used as appropriate.

Ge 2 is grown as a buffer layer that compensates for the lattice mismatch between the Si substrate 1 and GaAs 3 and reduces threading dislocations and other defects. Although the lattice constant of Ge 2 differs from that of the Si substrate 1 by about 4%, Ge 2 well compensates for this lattice mismatch and is a suitable material to prevent defects from occurring. Limited absorption of THz waves also makes Ge 2 a suitable material for use in this embodiment. Furthermore, Ge 2 can be advantageously used when the Si substrate 1 is made from a large-diameter silicon crystal.

The crystal of Ge 2 can be grown by techniques such as reduced-pressure CVD (chemical vapor deposition) using monogerman (GeH₄). It is known that growing a crystal of Ge 2 with the temperature of the Si substrate 1 maintained in the range of 600° C. to 900° C., both inclusive, provides a high-quality crystal that has few defects. However, when a crystal of Ge 2 is grown on a substrate made of a different material, i.e., the Si substrate 1, as in this embodiment, the temperature can be decreased to 300° C. to 500° C., both inclusive, so that the lattice mismatch between Ge 2 and the Si substrate 1 can be effectively compensated for. All or some of Ge 2 can therefore be grown with the temperature of the Si substrate 1 in the range of 300° C. to 500° C., both inclusive. It is also known that heating the grown layer of Ge 2 in an inert gas makes the threading dislocations in Ge 2 turn into dislocation loops near the interface with the Si substrate 1. This heat treatment prevents defects from reaching the interface between Ge 2 and GaAs 3.

GaAs 3, located between Ge 2 and LT-GaAs 4, is inserted to absorb the strain caused by the lattice mismatch between Ge 2 and GaAs 3 and to prevent Ge 2 from diffusing into LT-GaAs 4. The crystal of GaAs 3 can be grown by techniques such as MBE (molecular beam epitaxy). It is known that growing GaAs 3 with the temperature of the Si substrate 1 maintained in the range of 500° C. to 800° C., both inclusive, usually provides a high-quality crystal that has few defects. The high-quality crystal is a crystal that contains few defects such as dislocations and antisite defects and, for GaAs 3, also has a near-stoichiometric composition ratio of Ga to As, i.e., 1:1. More specifically, crystals that had a composition ratio Ga:As of (49.9 to 50.1):(50.1 to 49.9) (an element ratio Ga/As in the range of 0.9960 to 1.004, both inclusive) were found to have satisfactory quality. A composition ratio far from the stoichiometry causes several problems. For example, reduced conductivity of GaAs 3 may affect the resistance of the resulting photoconductive antenna, a composition shift may induce additional defects, and an increase in the number of free carriers may cause increased absorption of terahertz waves. In this embodiment, the crystal growth process is conducted with the temperature of the Si substrate 1 kept at 650° C. so that the strain due to the lattice mismatch between Ge 2 and GaAs 3 can be absorbed. The term strain, as used herein, refers to the distortion of a crystal associated with a shift of the lattice constant thereof from the inherent value. The range of this strain varies depending on the temperature at which GaAs 3 is grown, and usually extends about 100 nm or less from the interface between Ge 2 and GaAs 3 into GaAs 3. Growing LT-GaAs 4 on the surface of GaAs 3 with some residual strain would cause problems such as poor surface morphology and reduced critical thickness. It is therefore necessary that the surface of GaAs 3 that faces LT-GaAs 4 be highly crystalline, having few defects and a lattice constant close to the inherent value.

LT-GaAs 4 is grown as a functional layer of the photoconductive antenna. For use as a photoconductive antenna, LT-GaAs 4 is grown using techniques such as MBE (molecular beam epitaxy) in the temperature range of 200° C. to 400° C., both inclusive. It is known that growth in this temperature range causes an excess of As to get in LT-GaAs 4. This excessive As component is said to contribute to the characteristic short carrier lifetime. LT-GaAs 4 grown in accordance with this embodiment contained an excess of 0.1 atm % to 3 atm %, both inclusive, As. Processing the grown layer of LT-GaAs 4 at a temperature of 400° C. to 700° C. makes this excessive As component move and aggregate in the LT-GaAs crystal, forming clumps of As. This temperature treatment is also important in making LT-GaAs 4 semi-insulating and allowing this layer to perform the function of a photoconductive antenna. LT-GaAs 4 is not close to the stoichiometry; the element ratio Ga/As is less than 0.9960. Although in this embodiment LT-GaAs is used as a functional layer, compound semiconductors such as GaAs, InGaAs, AlGaAs, GaAsP, and InGaAsP can also be used. It is also possible to make such a compound semiconductor semi-insulating by means such as controlling the growth temperature or doping the semiconductor with an impurity. More specifically, the functional layer preferably has a resistivity of 1000 Ω·cm to 10000000 Ω·cm, both inclusive.

This temperature treatment is important but at the same time can cause Ge 2 and the material deposited thereon to mutually diffuse. In particular, if LT-GaAs 4 were deposited directly on Ge 2, Ge 2 would be very likely to diffuse during the temperature treatment for some reasons such as many defects in the crystal of LT-GaAs 4. It is therefore understood that Ge 2 should be coated with a highly crystalline layer of GaAs 3 that has few defects before growing LT-GaAs 4. Indeed, growing GaAs 3 in this embodiment on Ge 2 results in a limited mutual diffusion of Ge 2 and GaAs 3, extending only about 30 nm to 50 nm including both the hysteresis cycles during the temperature treatment and the growth of GaAs 3. This was verified by several analytical methods including TEM (transmission electron microscopy) and EDS (energy dispersive X-ray spectrometry). Furthermore, providing a stoichiometric composition to GaAs 3 under LT-GaAs 4 prevents Ga and As in LT-GaAs 4 and GaAs 3 from readily diffusing into the other layer during the heat treatment, thereby preventing functional damage to LT-GaAs 4.

As described above, it was found that inserting a 100-nm or thicker layer of GaAs 3 between Ge 2 and LT-GaAs 4 prevents crystallographic strains and diffusion out of Ge 2 from affecting LT-GaAs 4 and allows a high-quality crystal of LT-GaAs 4 to grow. Photoconductive antennas fabricated using this layer of LT-GaAs 4 worked without loss of performance such as reduced resistivity due to diffusion out of Ge 2 and other causes.

A photoconductive antenna according to this embodiment generates and detects a THz wave while the gap between the two coplanar coupled electrodes 5 in FIG. 1 is irradiated with an optical pulse and the excited carriers make LT-GaAs 4 conductive instantaneously. To generate a THz wave, the user applies a bias voltage across the electrodes 5. The generated carriers move parallel to the substrate plane as a flow of a current, and the photoconductive antenna emits a THz wave whose intensity is determined by the time derivative of the current and the magnitude of the bias voltage applied, with the pulse waveform depending on the duration of the incident optical pulse and the carrier lifetime. This pulse generally has a broad frequency spectrum in the THz range. Inserting the stoichiometrically composed GaAs 3 between LT-GaAs 4 and Ge 2 allows LT-GaAs 4 to grow with little strain. LT-GaAs 4 therefore contains few threading dislocations substantially perpendicular to the substrate plane. If LT-GaAs 4 contains many threading dislocations that can form conductive paths, these threading dislocations cause the layers of GaAs 3 and Ge 2 and the Si substrate 1 to form a conductive path together with LT-GaAs 4, reducing the resistance between the electrodes 5 of the photoconductive antenna. Such a decrease in the resistance between the electrodes 5 of the photoconductive antenna limits the maximum input voltage to the antenna and thus causes problems such as reduced power of the THz wave and shortened antenna lifetime. To detect the THz wave, the user measures the magnitude of the current that flows when the THz wave comes in the vicinity of the gap between the electrodes 5. The measured magnitude of the current corresponds to the intensity of the THz wave in a given time domain that depends on the duration of the incident optical pulse and the carrier lifetime. The current intensity levels in all time domains of interest are combined to detect the final form of the THz wave. The irradiation optical pulse can be, for example, a femtosecond laser that generates short pulses or an optical beat generated by superposing two waves that have slightly different frequencies. As for the wavelength of the irradiation light, it can be possible to use light that has a wavelength equal to or shorter than 870 nm, which corresponds to the band gap energy of LT-GaAs 4, 1.42 eV, so that the carriers can be excited. Even with light that has a wavelength more than 870 nm, however, the carriers can be excited through the effect of two-photon absorption or other events. When the photoconductive antenna is used as a detector, a decrease in the resistance between the electrodes 5 of the photoconductive antenna leads to problems such as an increase in the white noise caused by thermally generated dark currents.

For convenience in work such as wiring and optical alignment, many photoconductive antennas are designed to use the substrate side, i.e., on the side opposite the electrodes 5, to emit the generated THz wave and receive the THz wave to be detected. Although not illustrated, many photoconductive antennas have a hemispherical lens on the substrate side. Such a lens is made of semi-insulating Si, which allows THz waves to pass through with little loss, and is used for alignment purposes such as focusing THz waves. In this embodiment, THz waves are emitted and received through GaAs 3, Ge 2, and the Si substrate 1. As mentioned above, the Si substrate 1 and Ge 2 are materials that allow THz waves to pass through with little loss, whereas in GaAs 3 a phonon-induced absorption occurs at a range of frequencies around 8 THz. Thus GaAs 3 is a very important layer, but at the same time it is needed to select the optimal thickness therefor so that the essential information near 8 THz will be complete without loss due to absorption by phonons.

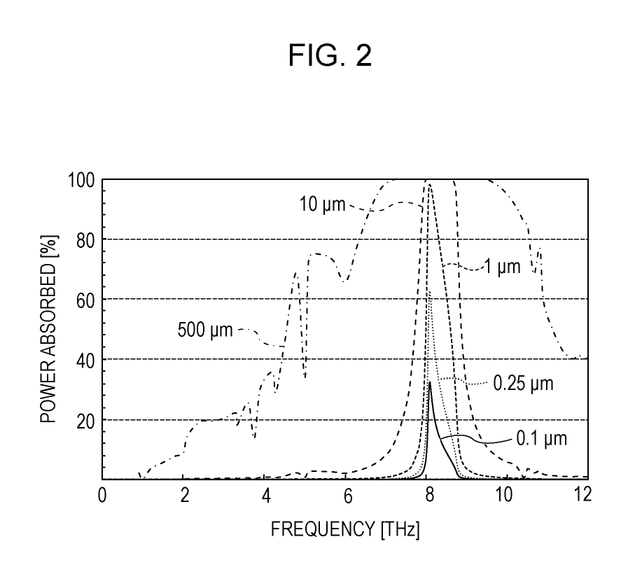

FIG. 2 shows the relationship between the thickness of the GaAs 3 and the power absorbed over the frequency range from 0 to 12 THz. Many of the ordinary photoconductive antennas are fabricated on a SI—GaAs substrate thicker than 100 μm and thus have a loss of THz waves as much as the power absorption by 500-μm thick GaAs typically illustrated in FIG. 2. Due to the power loss over a wide range around 8 THz, the THz waves finally detected after passing through the substrate have a narrowed frequency spectrum, even if the generator section emits THz waves that have a broad frequency spectrum. When a photoconductive antenna is used as a generator/detector for THz-band spectral analysis purposes, a narrowed frequency spectrum is an adverse incident that causes a lack of information in the THz range. As mentioned above, much of this spectral narrowing issue can be solved by replacing the SI—GaAs substrate with a Si substrate 1.

This embodiment allows the user to adjust the power absorption by changing the thickness of GaAs 3 and thereby to make the frequency spectrum complete near 8 THz. A photoconductive antenna that had GaAs 3 whose thickness was 0.1 μm, i.e., the aforementioned minimum thickness requirement for the intended performance, had a peak power absorption of about 30% near 8 THz. This is enough to achieve a broad and complete frequency spectrum without loss of the S/N (signal to noise ratio). Achieving a broad and complete frequency spectrum without loss of the S/N required that the thickness of GaAs 3 be about 0.25 μm or less. A broad and complete frequency spectrum was still obtained when the thickness of GaAs 3 was 1 μm, although with a one-digit drop in S/N in a certain range. In contrast, photoconductive antennas fabricated with GaAs 3 thicker than 1 μm had an extremely low S/N in a particular range, in which the loss of the S/N was too great to recover by data processing and no guarantee could be given for the accuracy of data. It was therefore understood that fabricating a photoconductive antenna that provides a broad and complete frequency spectrum requires that the thickness of GaAs 3 be 1 μm or less.

This embodiment of a photoconductive antenna therefore enables the fabrication of photoconductive antennas that provide a broad and complete frequency spectrum without loss of performance, with the data complete even near 8 THz.

### Embodiment 2

Embodiment 2 is described. As illustrated in FIG. 3, this embodiment has a buffer layer 6, which is a thin film of Si₍₁₋ₓ₎Ge, where x is a composition ratio, and has an increasing gradient of the composition ratio x in the direction of film growth, i.e., from the Si substrate 1 side to the GaAs 3 side. More specifically, the composition ratio x=0 at the end on the Si substrate 1 side, then x gradually changes, and x=1 at the end on the GaAs 3 side. The thin film of Si₍₁₋ₓ₎Geₓ can be grown in the crystalline form by techniques such as reduced-pressure CVD (chemical vapor deposition) using monosilane (SiH₄) and monogerman (GeH₄). The composition ratio x can be controlled by the flow rates of the gases; gradually changing the flow rates of the gases leads to the composition ratio x gradually changing in the Si₍₁₋ₓ₎Geₓ film.

The use of a thin film of Si₍₁₋ₓ₎Geₓ as the buffer layer 6 provides a lattice constant gradient that extends from the Si substrate 1 to GaAs 3. As a result, the density of threading dislocations and other defects is reduced in GaAs 3 and LT-GaAs 4. Threading dislocations in a crystal create unintended current paths and thus can cause poor yield of photoconductive antennas that have LT-GaAs 4 as a functional layer. Poor yield can be prevented by using a thin film of Si₍₁₋ₓ₎Geₓ as the buffer layer 6. A thin film of Si₍₁₋ₓ₎Geₓ, made of Si and Ge, which both absorb only a limited amount of THz waves, is also suitable for use in photoconductive antennas. A study confirmed that a grown layer of GaAs 3 on a thin film of Si₍₁₋ₓ₎Geₓ was crystalline enough to prevent Ge from diffusing out of Si₍₁₋ₓ₎Geₓ.

This embodiment of a photoconductive antenna therefore enables the fabrication of photoconductive antenna that provide a broad and complete frequency spectrum without loss of performance, with the data complete even near 8 THz.

### Embodiment 3

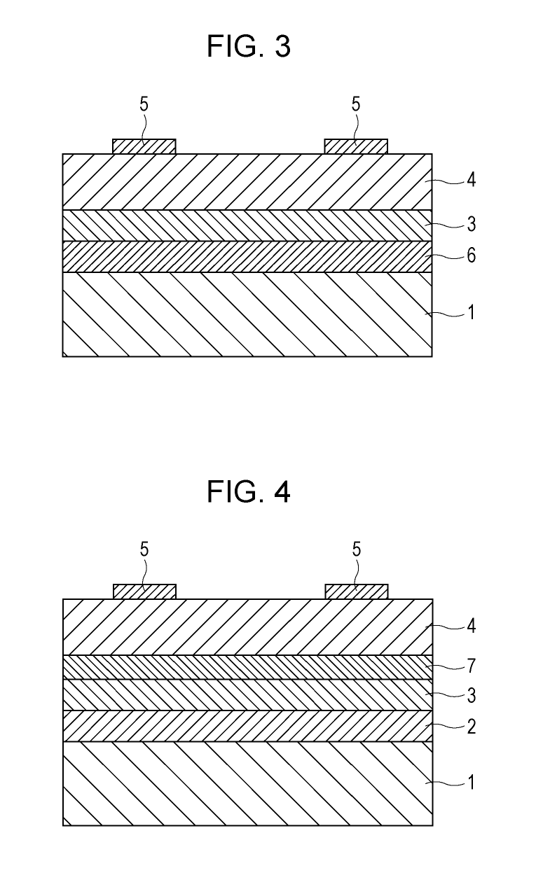

Embodiment 3 is described. As illustrated in FIG. 4, this embodiment has a current barrier layer 7 between GaAs 3 and LT-GaAs 4. The current barrier layer 7 can be, for example, a monolayer of AlₓGa₍₁₋ₓ₎As (0.5≦x≦1) or similar compound semiconductors or an alternate stack of AlₓGa₍₁₋ₓ₎As (0.5≦x≦1) and GaAs or similar combinations of compound semiconductors. This current barrier layer 7 can be grown in the crystalline form by techniques such as MBE (molecular beam epitaxy).

This current barrier layer 8 prevents the current that flows through LT-GaAs 4 between the electrodes 5 substantially parallel to the Si substrate 1 from flowing into the layers of GaAs 3 and Ge 2. This means that AlₓGa₍₁₋ₓ₎As in the current barrier layer 7 serves as an interband barrier and therefore should be about 10 nm thick to prevent tunnel currents. This also applies when the current barrier layer 7 is an alternate stack of AlₓGa₍₁₋ₓ₎As (0.5≦x≦1) and GaAs; each layer of AlₓGa₍₁₋ₓ₎As should be about 10 nm thick. Since AlₓGa₍₁₋ₓ₎As also absorbs THz waves, the thickness of the current barrier layer 7 should be determined in consideration of the broadness and completeness of the resulting frequency spectrum. However, the absorption of THz waves by TO phonons in AlₓGa₍₁₋ₓ₎As peaks at a different position from that in GaAs. With this in consideration, a layer of AlₓGa₍₁₋ₓ₎As can be used without major problems unless the thickness thereof exceeds about 1 μm. When the current barrier layer 7 is an alternate stack of AlₓGa₍₁₋ₓ₎As (0.5≦x≦1) and GaAs, however, greater care is needed to avoid a lack of information in the frequency spectrum due to absorption by GaAs. Therefore the combined thickness of GaAs in the current barrier layer 7, which depends on the number of GaAs layers stacked, and the thickness of the layer of GaAs 3 should not total more than 1 μm. In most of the cases where the current barrier layer 7 is an alternate stack of some layers of AlₓGa₍₁₋ₓ₎As (0.5≦x≦1) and GaAs, however, the function can be performed without needing many layers stacked. The total thickness of GaAs in the current barrier layer 7 is therefore on the order of several tens of nanometers, and the integrity of the frequency spectrum is maintained. The barrier layer 7 can also be an alternate stack of AlₓGa₍₁₋ₓ₎As (0.5≦x≦1) and InGaP. In this case, the thickness of the barrier layer 7 is determined in consideration of the completeness of the resulting THz-wave frequency spectrum rather than with care to the total thickness of GaAs because the absorption by TO phonons in InGaP peaks at a different position from that in GaAs. Indeed, the total thickness of InGaP in the current barrier layer 7 is on the order of several tens of nanometers; the integrity of the frequency spectrum is maintained in most cases.

When the photoconductive antenna is used to detect THz waves, especially, it is important that the resistance between the electrodes 5 be high enough that the thermally induced Johnson noise should not affect the S/N of the data. Inserting the current barrier layer 7 between GaAs 3 and LT-GaAs 4 prevents the current that flows through LT-GaAs 4 between the electrodes 5 substantially parallel to the Si substrate 1 from flowing into the layers of GaAs 3 and Ge 2; the barrier layer 7 increases the resistance of the photoconductive antenna by reducing current paths. A study confirmed that the resulting frequency spectrum data have high S/N ratios over a broad frequency range.

Diffusion of Ge 2 in the current barrier layer 7 affects the function of the current barrier layer 7 for some reasons such as a change in the barrier height of AlₓGa₍₁₋ₓ₎As (0.5≦x≦1) and the behavior of Ge 2 as an impurity. A study has found that GaAs 3 in this embodiment prevents Ge 2 from diffusing into the current barrier layer 7 and LT-GaAs 4 and thus is essential to improve the performance of the photoconductive antenna.

This embodiment of a photoconductive antenna therefore enables the fabrication of photoconductive antenna that provide a broad and complete frequency spectrum without loss of performance, with the data complete even near 8 THz.

### Embodiment 4

Embodiment 4 relates to a terahertz time domain spectroscopy (THz-TDS) system that uses a photoconductive antenna equivalent to those described in Embodiments 1 to 3.

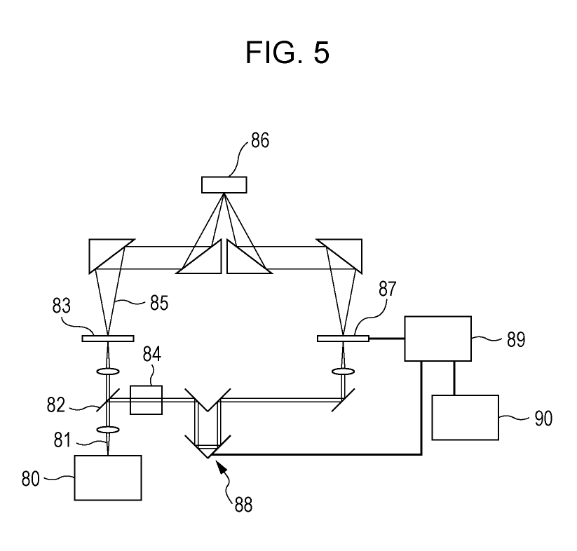

FIG. 5 illustrates an example of the structure of a terahertz time domain spectroscopy system according to this embodiment. This terahertz time domain spectroscopy system uses terahertz waves that contain electromagnetic wave components in the frequency range of 30 GHz to 30 THz, both inclusive.

In FIG. 5, an excitation optical pulse generator 80 emits an excitation optical pulse 81. The excitation optical pulse generator 80 can be a fiber laser, for example. The excitation optical pulse 81 is a 1.5-μm wavelength pulse laser that has a duration (the full width at half maximum in the power diagram) of about 30 fs. The excitation optical pulse 81 is divided into two beams at a beam splitter 82. One beam of the excitation optical pulse 81 is incident on a terahertz-wave pulse generator (a generator section) 83, whereas the other is incident on a second harmonic generator 84.

The terahertz-wave pulse generator 83 can be a photoconductive antenna equivalent to any of those according to the above embodiments. The component of the excitation optical pulse 81 incident on the generator 83 is focused on the light-absorbing portion of the photoconductive antenna through a lens with a beam diameter of about 10 μm.

The terahertz-wave pulse 85 is emitted as strong radiation toward the back of the substrate on which the generating antenna is located. Thus a silicon hemispherical lens may be placed on the back of the substrate so that more power is radiated to the space.

This structure allows the user to radiate terahertz-wave pulses 85 with different durations (the full width at half maximum) on the order of several hundreds of femtoseconds to several picoseconds.

The terahertz-wave pulse 85 radiated to the space is focused on a sample 86 by optical elements such as lenses and mirrors. The terahertz-wave pulse 85 reflected by the sample 86 is guided to a terahertz-wave pulse detector (a detector section) 87 by optical elements.

The other of the two beams of the excitation optical pulse 81 split at the beam splitter 82, which is incident on the second harmonic generator 84, is converted into a 0.8-μm wavelength pulse laser through the second harmonic conversion process. The second harmonic generator can be a PPLN (periodically poled lithium niobate) crystal, for example. Any wavelengths generated through other nonlinear processes and the 1.5-μm wavelength laser that comes out with no wavelength shift are removed from the excitation optical pulse 81 (or attenuated) by means such as a dichroic mirror (not illustrated).

Converted into a 0.8-μm wavelength beam, the excitation optical pulse 81 is guided to the terahertz-wave pulse detector 87 through an excitation-light delaying system 88.

The terahertz-wave pulse detector 87 can be a photoconductive antenna equivalent to any of those according to the above embodiments. The branch of the excitation optical pulse 81 on the detector side can be the 0.8-μm wavelength beam produced at the second harmonic generator 84; however, it is also possible to use the 1.5-μm wavelength beam without wavelength conversion. The optical excitation carriers generated in the photoconductive layer are accelerated by the electric field of the terahertz-wave pulse 85 and induce a current that flows between the electrodes. The magnitude of this current indicates the intensity of the electric field of the terahertz-wave pulse 85 in the time for which the photoelectric current flows. The current can be converted into a voltage by using a current-to-voltage converter. Sweeping the time of delay of the excitation optical pulse 81 by using the excitation-light delaying system 88 that includes elements such as a movable retroreflector reconstitutes a time waveform for the intensity of the electric field of the terahertz-wave pulse 85. A processor 89 has several purposes such as controlling the duration of the delay provided by the excitation-light delaying system 88. Information on the sample 86 (e.g., the complex refractive index and the shape) is obtained from the time waveform of the terahertz-wave pulse 85 and the frequency components thereof and shown on a display 90.

Furthermore, measuring the time interval between the components of the terahertz-wave pulse 85 reflected by the surface of and an interface in the sample 86 provides the spacing between these planes (the time-of-flight method). Scanning the sample 86 through several measurement points thereon provides a tomographic image. Although in FIG. 5 the terahertz-wave pulse 85 reflected by the sample 86 is detected, it is also possible to detect the terahertz-wave pulse 85 that passes through the sample 86.

Such a material tester allows the user to identify, image, or otherwise characterize the material of interest with high accuracy. These features make the material tester useful in fields including medical practice and treatment, cosmetology and esthetics, and industrial inspection.

### EXAMPLE

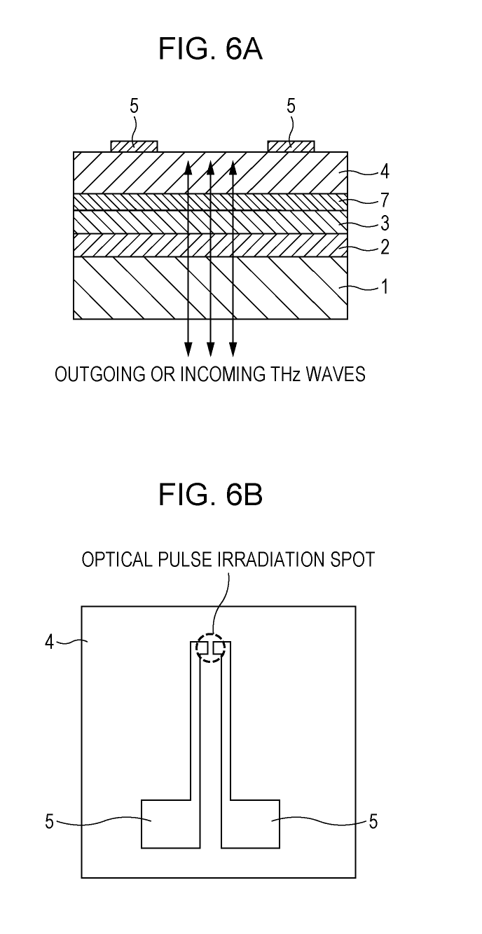

An example of the invention is described with reference to FIG. 6. FIGS. 6A and 6B are a cross-sectional view and a top view, respectively, of a photoconductive antenna according to this example. FIGS. 6A and 6B illustrate a photoconductive antenna produced by growing crystals of Ge (a Ge layer) 2, GaAs (a GaAs layer) 3, a current barrier layer 7, and LT-GaAs (a LT-GaAs layer) 4 on a Si substrate 1 in this order and then placing electrodes 5.

In this example, the Si substrate 1 was made of silicon that had a resistivity of 5 kΩ·cm in order that the loss of THz waves due to absorption by free carriers could be reduced. The substrate had an orientation of (100) and an off-angle tilted at 3° to 8° from the orientation.

A 500-nm layer of Ge 2 was then grown to provide a buffer layer to compensate for the lattice mismatch between the Si substrate 1 and GaAs 3 and reduce threading dislocations and other defects. In this example, Ge 2 was successfully grown with a uniform resistivity and a dislocation density on the order of 1×10⁸ to 5×10⁸ (cm⁻²) on the 8-inch Si disk. Ge 2 was grown by reduced-pressure CVD (chemical vapor deposition) using monogerman (GeH₄). In this embodiment, the crystal was grown at a temperature of 500° C. so that the lattice mismatch between Ge 2 and the Si substrate 1 could be effectively cancelled.

GaAs 3, located between Ge 2 and LT-GaAs 4, is inserted to absorb the strain caused by the lattice mismatch between Ge 2 and GaAs 3 and to prevent Ge 2 from diffusing into the current barrier layer 7 and LT-GaAs 4. The crystal of GaAs 3 was grown by MBE (molecular beam epitaxy) to be 200 nm thick. In this example, the crystal of GaAs 3 was grown with the temperature of the Si substrate 1 maintained at 650° C., and a high-quality crystal having few defects was obtained. The grown layer of GaAs 3 in this example achieved the stoichiometry, i.e., Ga:As=50.00:50.00, and the strain extended about 100 nm from the interface between Ge 2 and GaAs 3 into GaAs 3.

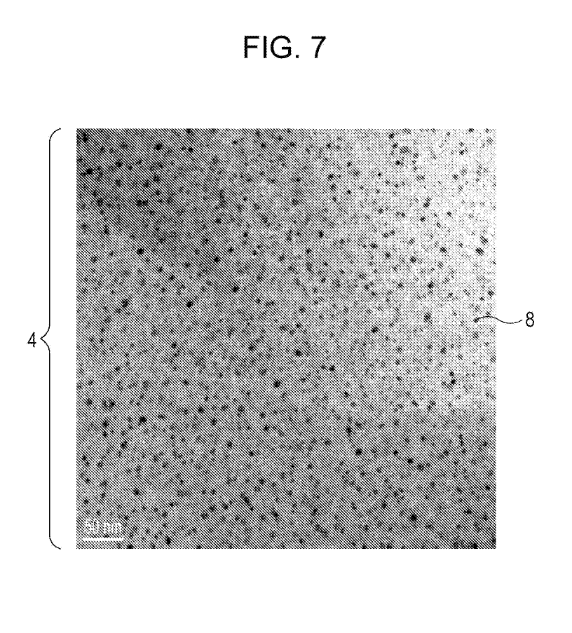

Then the current barrier layer 7 was inserted between GaAs 3 and LT-GaAs 4. To form the current barrier layer 7, ten layers each of AlₓGa₍₁₋ₓ₎As (0.5≦x≦1) and GaAs were alternately stacked, each layer having a thickness of 10 nm. This current barrier layer 7 was found to be effective in reducing threading dislocations as well; the dislocation density was on the order of 1×10⁷ to 5×10⁷ (cm⁻²) in the portion of the current barrier layer 7 bordering LT-GaAs 4, declined compared to 1×10⁸ to 5×10⁸ (cm⁻²) in the layer of GaAs 3. LT-GaAs 4, the functional layer of the photoconductive antenna, was grown by MBE to be 2 μm thick with the substrate temperature at 200° C. In this example, the grown layer contained an excess of 2 atm % As. Processing the grown layer of LT-GaAs 4 at a temperature of 550° C. made this excessive As component move and aggregate in the LT-GaAs crystal, forming clumps 8 of As each measuring about 10 nm in diameter as in the TEM image of FIG. 7. The size of the As clumps 8 can be controlled by the temperature and the duration of treatment. This temperature treatment is also important in making LT-GaAs 4 semi-insulating and allowing this layer to perform the function of a photoconductive antenna. The resistivity of LT-GaAs 4 in this example was about 100000 Ω·cm.

This temperature treatment is important but at the same time can cause Ge 2 and the material deposited thereon to mutually diffuse. In this example, however, inserting the stoichiometric GaAs 3 limited the mutual diffusion of Ge 2 and GaAs 3 to a very narrow range, only about 30 nm including both the hysteresis cycles during the temperature treatment and the growth of GaAs 3. This was verified by several analytical methods including TEM (transmission electron microscopy) and EDS (energy dispersive X-ray spectrometry). The density of threading dislocations in LT-GaAs 4 was on the order of 1×10⁷ to 5×10⁷ (cm⁻²).

The photoconductive antenna according to this example generates and detects a THz wave while the gap extending about 5 μm to 50 μm between the two coplanar coupled electrodes 5 in FIG. 6 is irradiated with an optical pulse and the excited carriers make LT-GaAs 4 conductive instantaneously. To generate a THz wave, the user applies a bias voltage across the electrodes 5. The generated carriers move parallel to the substrate plane as a flow of a current, and the antenna emits a THz wave whose intensity is determined by the time derivative of the current and the magnitude of the bias voltage applied, with the pulse waveform depending on the duration of the incident optical pulse and the carrier lifetime. This pulse generally has a broad frequency spectrum in the THz range. Inserting the stoichiometrically composed GaAs 3 between LT-GaAs 4 and Ge 2 allows LT-GaAs 4 to grow with little strain. LT-GaAs 4 therefore contains few threading dislocations substantially perpendicular to the substrate plane. If LT-GaAs 4 contains many threading dislocations that can form conductive paths, these threading dislocations cause the layers of GaAs 3 and Ge 2 and the Si substrate 1 to form a conductive path together with LT-GaAs 4, reducing the resistance between the electrodes 5 of the photoconductive antenna. In the photoconductive antenna of this example, the grown layer of LT-GaAs 4 contained very few threading dislocations owing to the advantages of certain aspects of the invention, hence the resistance between the electrodes 5 as high as 20 MΩ. The high resistance of the photoconductive antenna fabricated in this example between the electrodes 5 allowed voltage levels equal to or more than 100 V to be applied to the antenna, resulting in efficient generation of THz waves. When the photoconductive antenna was used as a detector, the effect of the white noise associated with thermally generated dark currents was at the lower limit of quantification because of the high resistance between the electrodes 5 of the antenna.

For convenience in work such as wiring and optical alignment, many photoconductive antennas are designed to use the substrate side, i.e., on the side opposite the electrodes 5, to emit the generated THz wave and receive the THz wave to be detected. Although not illustrated, many photoconductive antennas have a hemispherical lens on the substrate side. Such a lens is made of semi-insulating Si, which allows THz waves to pass through with little loss, and is used for alignment purposes such as focusing THz waves. In this example, THz waves are emitted and received through GaAs 3, Ge 2, and the Si substrate 1. As mentioned above, the Si substrate 1 and Ge 2 are materials that allow THz waves to pass through with little loss, whereas in GaAs 3 a phonon-induced absorption occurs at a range of frequencies around 8 THz. Thus GaAs 3 is a very important layer, but at the same time it is needed to select the optimal thickness therefor so that the essential information near 8 THz will be complete without loss due to absorption by phonons.

The photoconductive antenna according to this example, which had the 0.2-μm layer of GaAs 3 and the current barrier layer 7, had a peak power absorption of about 50% near 8 THz. This was enough to achieve a broad and complete frequency spectrum without loss of the S/N (signal to noise ratio).

This example of a photoconductive antenna therefore enables the fabrication of photoconductive antennas that provide a broad and complete frequency spectrum without loss of performance, with the data complete even near 8 THz.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

For example, photoconductive antennas according to certain aspects of the invention may have an additional layer besides the stack of a Si substrate, a buffer layer that contains Ge, a first semiconductor layer that contains Ga and As, a second semiconductor layer that contains Ga and As, and an electrode unless the advantages of such aspects of the invention are reduced. Such an additional layer can be located between the substrate and the buffer layer, between two adjacent layers, or the second semiconductor layer and the electrode.

This application claims the benefit of Japanese Patent Application No. 2013-046576 filed Mar. 8, 2013 and No. 2014-012784 filed Jan. 27, 2014, which are hereby incorporated by reference herein in their entirety.

What is claimed is:

1. A photoconductive antenna that generates and detects a terahertz wave, the photoconductive antenna comprising:
a Si substrate; a buffer layer containing Ge; a first semiconductor layer containing Ga and As; a second semiconductor layer containing Ga and As; and an electrode in this order,
the second semiconductor layer having an element ratio Ga/As smaller than an element ratio Ga/As of the first semiconductor layer.

2. The photoconductive antenna according to claim 1, wherein
the first semiconductor layer has a thickness of 1 μm or less.

3. The photoconductive antenna according to claim 1, wherein
the first semiconductor layer has a thickness of 100 nm to 1 μm, both inclusive.

4. The photoconductive antenna according to claim 1, wherein
the first semiconductor layer has a thickness of 100 nm to 250 nm, both inclusive.

5. The photoconductive antenna according to claim 1, wherein
the first semiconductor layer is grown at a temperature of 500° C. to 800° C., both inclusive.

6. The photoconductive antenna according to claim 1, wherein
the element ratio Ga/As of the first semiconductor layer is in a range of 0.9960 to 1.004, both inclusive.

7. The photoconductive antenna according to claim 1, wherein
the second semiconductor layer is made of at least one of GaAs, InGaAs, AlGaAs, GaAsP, and InGaAsP.

8. The photoconductive antenna according to claim 1, wherein
the second semiconductor layer has a resistivity of 1000 Ω·cm to 10000000 Ω·cm, both inclusive.

9. The photoconductive antenna according to claim 1, wherein
the second semiconductor layer is made of GaAs; and
the second semiconductor layer is grown at a temperature of 200° C. and 400° C., both inclusive.

10. The photoconductive antenna according to claim 1, wherein
the second semiconductor layer is made of GaAs; and
the element ratio Ga/As of the second semiconductor layer is less than 0.9960.

11. The photoconductive antenna according to claim 1, wherein
the second semiconductor layer is made of GaAs; and
the second semiconductor layer contains an excess of 0.1 atm % to 3 atm %, both inclusive, As.

12. The photoconductive antenna according to claim 1, wherein
the buffer layer is made of Si₍₁₋ₓ₎Geₓ, where x is a composition ratio, 0≦x≦1; and
the buffer layer has an increasing gradient of the composition ratio x from a Si substrate side to a first semiconductor layer side.

13. The photoconductive antenna according to claim 1, further comprising
a barrier layer between the first semiconductor layer and the second semiconductor layer, the barrier layer containing AlₓGa₍₁₋ₓ₎As, 0.5≦x≦1.

14. The photoconductive antenna according to claim 13, wherein
the barrier layer has an alternate stack of a layer made of AlₓGa₍₁₋ₓ₎As, 0.5≦x≦1, and a layer made of GaAs.

15. The photoconductive antenna according to claim 13, wherein
the barrier layer has an alternate stack of a layer made of AlₓGa₍₁₋ₓ₎As, 0.5≦x≦1, and a layer made of InGaP.

16. The photoconductive antenna according to claim 1, wherein
the electrode has a plurality of electrodes; and
the plurality of electrodes are located on the second semiconductor layer.

17. A method for producing a photoconductive antenna that generates and detects a terahertz wave, the method comprising
forming a buffer layer containing Ge, a first semiconductor layer containing Ga and As, a second semiconductor layer containing Ga and As, and an electrode in this order on a Si substrate,
the second semiconductor layer having an element ratio Ga/As smaller than an element ratio Ga/As of the first semiconductor layer.

18. The method for producing a photoconductive antenna according to claim 17, wherein
the first semiconductor layer is grown at a temperature of 500° C. to 800° C., both inclusive.

19. The method for producing a photoconductive antenna according to claim 17, wherein
the second semiconductor layer is made of GaAs; and
the second semiconductor layer is grown at a temperature of 200° C. and 400° C., both inclusive.

20. A terahertz time domain spectroscopy system comprising:
a generator section that generates a terahertz wave; and
a detector section that detects the terahertz wave,
at least one of the generator section and the detector section having the photoconductive antenna according to claim 1.
